(19) United States
(12) Patent Application Publication
(10) Pub. No.: US 2024/0206107 A1
(43) Pub. Date: Jun. 20, 2024

(54) COOLING STRUCTURE FOR DMS MODULE

(71) Applicant: Veoneer US, LLC, Southfield, MI (US)

(72) Inventor: Jacob Pusheck, San Diego, CA (US)

(21) Appl. No.: 18/085,507

(22) Filed: Dec. 20, 2022

(51) Int. Cl. H05K 7/20; H04N 23/20; H04N 23/51; H04N 23/52; H05K 5/00

(52) U.S. Cl. CPC H05K 7/20127; H04N 23/20; H04N 23/51; H04N 23/52; H05K 5/0026; H05K 7/20409

(57) ABSTRACT

A driver monitoring system module comprises a housing, a first circuit board, and a second circuit board. The first circuit board is generally mounted at a first location within the housing. The second circuit board is generally mounted at a second location on an exterior surface of the housing. The first circuit board and the second circuit board are partially overlapped in a first direction and separated by a predefined distance in a second direction. The exterior surface of the housing generally defines a passage between overlapped portions of the first circuit board and the second circuit board that allows ambient air to pass between the first circuit board and the second circuit board to provide convective cooling.

### FIELD OF THE INVENTION

The invention relates to sensor housings generally and, more particularly, to a method and/or apparatus for implementing a cooling structure for a driver monitoring system (DMS) module.

### BACKGROUND

A driver monitoring system (DMS) generally includes a camera and an infra-red (IR) light source. For a third-generation driver monitoring system, a lens axis of the camera and the IR light source (e.g., a number of infra-red light emitting diodes (IR LEDS) are generally positioned to achieve a desired pupil illumination. This creates a problem with heat, as the IR LEDS create a significant amount of heat, which can disturb an imager (image sensor) of the camera. To reduce this heat problem, two printed circuit boards (PCBs) are used (one for the camera and one for the IR LEDS). In order to still maintain the distance from the lens axis to the IR LEDS, the two PCBs are overlapped. The overlapped boards still have the problem of transferring heat from the IR LEDS to the imager of the camera.

It would be desirable to implement a cooling structure for a driver monitoring system (DMS) module.

### SUMMARY

The invention concerns a driver monitoring system module comprising a housing, a first circuit board, and a second circuit board. The first circuit board is generally mounted at a first location within the housing. The second circuit board is generally mounted at a second location on an exterior surface of the housing. The first circuit board and the second circuit board are partially overlapped in a first direction and separated by a predefined distance in a second direction. The exterior surface of the housing generally defines a passage between overlapped portions of the first circuit board and the second circuit board that allows ambient air to pass between the first circuit board and the second circuit board to provide convective cooling.

### BRIEF DESCRIPTION OF THE FIGURES

Embodiments of the invention will be apparent from the following detailed description and the appended claims and drawings.

FIG. 1 is a diagram illustrating a perspective view of a driver monitoring system (DMS) module in accordance with an embodiment of the invention.

FIG. 2 is a diagram illustrating a cooling structure of a driver monitoring system (DMS) module in accordance with an embodiment of the invention.

FIG. 3 is a diagram illustrating a cross-sectional view of a driver monitoring system (DMS) module in accordance with an embodiment of the invention.

### DETAILED DESCRIPTION OF THE EMBODIMENTS

Embodiments of the present invention include providing a cooling structure for a driver monitoring system (DMS) module that may (i) implement separate camera and IR LED printed circuit boards (PCBs), (ii) add a hole between the IR LED PCB and the camera PCB to form a heat conductive channel to open air, (iii) reduce the amount of heat reaching the camera PCB and components, (iv) provide a housing with a pass-through channel (or passage) between the camera circuit board and the IR LED PCB that allows ambient air to pass through to provide convective cooling, (v) provide a channel that is parallel with a plane of the camera PCB and a plane of the IR LED PCB, (vi) be molded into a housing of the DMS module, and/or (vii) allow the separate camera and LED PCBs to overlap while providing a thermal break.

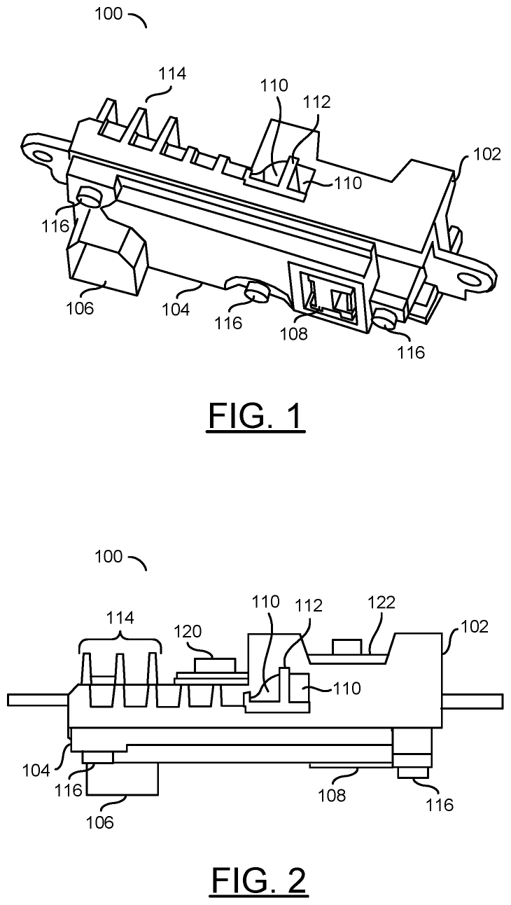

Referring to FIG. 1, a diagram is shown illustrating a perspective view of a driver monitoring system (DMS) module in accordance with an embodiment of the invention. In various embodiments, an apparatus 100 may implement a driver monitoring system (DMS) module. In an example, the apparatus 100 may implement a third-generation driver monitoring system (DMS3) module. The apparatus 100 generally includes a housing comprising an upper housing 102 and a lower housing 104. The lower housing 104 may comprise an opening for a first connector 106 and an opening for a second connector 108. The upper housing 102 may comprise a channel 110. The channel 110 generally allows ambient air to flow through providing convective cooling. In various embodiments, the channel 110 is defined by an exterior surface of the upper housing 102. In an example, the channel 110 may comprise more than one passage separated by a wall 112. The upper housing 102 may comprise a finned structure 114. In an example, the finned structure 114 may comprise a plurality (e.g., three, etc.) of fins. The finned structure 114 may provide additional convective cooling of the upper housing 102.

The upper housing 102 and the lower housing 104 may be implemented as a non-conductive enclosure. In an example, the upper housing 102 and the lower housing 104 fastened together by a plurality of fasteners (e.g., screws, etc.) 116. In some embodiments, the upper housing 102 may be configured to provide an environmentally sealed enclosure while mated with the lower housing 104. In an example, the fasteners 114 may be configured to apply a compressive force evenly to a gasket (or sealant) placed between the upper housing 102 and the lower housing 104. The upper housing 102 and the lower housing 104 may protect components and devices of the driver monitoring system (DMS) module 100.

In an example, the upper housing 102 and the lower housing 104 may be formed of a plastic or resin-based material. In various embodiments, the plastic or resin-based material may include, but is not limited to polyamide (NYLON), polybutylene terephthalate (PBT), polypropylene, polyethylene terephthalate (PET), acrylonitrile butadiene styrene (ABS), and/or various alloys and/or fillers of the resins. However, other materials may be implemented to meet the design criteria of a particular application. In various embodiments, the upper housing 102 and the lower housing 104 may be formed using various techniques including, but not limited to, casting, injection molding, and three-dimensional printing.

In an example, the first connector 106 may be implemented as an electrical connector of the driver monitoring system (DMS) module 100. In an example, the first connector 106 may be operational to perform one or more electrical functions. The electrical functions may include, but are not limited to, providing grounding paths for electrical components inside the driver monitoring system (DMS) module 100 to the exterior of the driver monitoring system (DMS) module 100 and/or transfer electrical inputs from different circuits in a vehicle to electronic components mounted inside the driver monitoring system (DMS) module 100. In an example, the first connector 106 may be implemented as a coaxial electrical connector. In an example, the first connector 106 may be configured to supply both power and data to a camera module mounted inside the driver monitoring system (DMS) module 100.

In various embodiments, the second connector 108 generally comprises a socket having one or more integrated connectors attached to one or more printed circuit boards (PCBs) of the driver monitoring system (DMS) module 100. In an example, the second connector 108 may be configured to connect the driver monitoring system (DMS) module 100 to an electronic bus of the vehicle. In an example, the second connector 108 may be implemented as a 4-pin power connector configured to drive an IR LED module of the driver monitoring system (DMS) module 100. In an example, the second connector 108 may be configured to provide pulsed power to the IR LED module based on a desired exposure setting (or level). In an example, the exposure setting may be prescribed by an auto exposure algorithm implemented by the driver monitoring system (DMS) module 100.

The driver monitoring system (DMS) module 100 may comprise two or more printed circuit boards containing electrical circuitry configured to perform the electrical functions of the driver monitoring system (DMS) module 100. In various embodiments, electronic components mounted in the upper housing 102 may comprise one or more IR LEDS and driver circuitry. In various embodiments, electronic components mounted in the lower housing 104 may comprise a camera module comprising a lens assembly, an image sensor (or imager), and associated circuitry. In various embodiments, the upper housing 102 is generally configured to allow the lens assembly of the camera module to extend through the exterior surface of the upper housing 102. In various embodiments, the upper housing 102 is generally configured to form an environmental seal with the lens assembly of the camera module.

Referring to FIG. 2, a diagram is shown showing a side view illustrating a cooling structure of the driver monitoring system (DMS) module 100 in accordance with an embodiment of the invention. In an example, a lens assembly 120 of the camera module may extend above the exterior surface of the upper housing 102. In an example, the IR LED module may comprise a plurality of IR LEDS and driver circuitry mounted on an IR LED printed circuit board (PCB) 122. The IR LED PCB 122 may be mounted to an upper portion of the exterior surface of the upper housing 102. In an example, the IR LED module may be implemented comprising two IR LED arrays, with each IR LED array comprising two IR LEDS. In an example, the IR LED PCB 122 may be implemented having two circuits (e.g., one circuit per IR LED array).

The one or more channels 110 are generally oriented to run between the IR LED PCB 122 and a printed circuit board of the camera module (not visible) mounted within the housing of the driver monitoring system (DMS) module 100. The one or more channels 110 are generally oriented to run parallel with a plane of the IR LED PCB 122 and perpendicular to an optical axis of the lens assembly 120. In some embodiments, the upper housing 102 may include the wall 112 between the two or more channels 110 to provide additional support for the IR LED PCB 122.

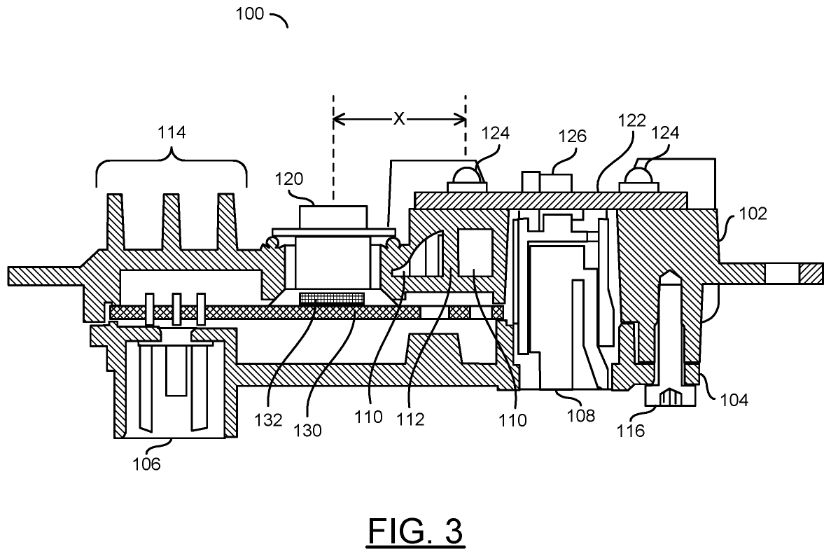

Referring to FIG. 3, a diagram is shown illustrating a cross-sectional view of a driver monitoring system (DMS) module in accordance with an embodiment of the invention. The IR LED PCB 122 may be mounted to an upper portion of the exterior surface of the upper housing 102. In an example, the IR LED PCB 122 may implement an illuminator circuit board. In an example, the IR LED PCB 122 comprises a plurality of IR LEDS 124 and driver circuitry 126. In an example, the IR LED PCB 122 may comprise four IR LEDS arranged in two banks of two IR LEDs along with discrete components to drive the IR LEDS.

The one or more channels 110 are generally oriented to run between the IR LED PCB 122 and a printed circuit board (PCB) 130 of the camera module. The camera module PCB 130 is generally mounted within the lower housing 104. The camera module PCB 130 generally implements a camera circuit board. The camera module PCB 130 generally supports the lens assembly 120 and provides electrical connections for an image sensor chip 132 of the camera module. In an example, the camera module PCB 130 generally contains drivers, the image sensor chip 132, and power circuitry to both capture image data and communicate the image data to the electronic systems of the vehicle. The one or more channels 110 are generally oriented to run perpendicular to an optical axis of the lens assembly 120. In some embodiments, the upper housing 102 may include a wall 112 between the one or more channels 110 to provide addition support for the IR LED PCB 122. In various embodiments, an overlap between the camera module PCB 130 and the IR LED PCB 122 is configured to provide a separation (e.g., X) between optical axis of the lens assembly 120 and the IR LEDS 124 of the IR LED module. In an example, the magnitude of separation X is generally chosen to achieve a pupil illumination criteria of a particular application.

The terms “may” and “generally” when used herein in conjunction with “is (are)” and verbs are meant to communicate the intention that the description is exemplary and believed to be broad enough to encompass both the specific examples presented in the disclosure as well as alternative examples that could be derived based on the disclosure. The terms “may” and “generally” as used herein should not be construed to necessarily imply the desirability or possibility of omitting a corresponding element.

The designations of various components, modules and/or circuits as “a”-“n”, when used herein, disclose either a singular component, module and/or circuit or a plurality of such components, modules and/or circuits, with the “n” designation applied to mean any particular integer number. Different components, modules and/or circuits that each have instances (or occurrences) with designations of “a”-“n” may indicate that the different components, modules and/or circuits may have a matching number of instances or a different number of instances. The instance designated “a” may represent a first of a plurality of instances and the instance “n” may refer to a last of a plurality of instances, while not implying a particular number of instances.

While the invention has been particularly shown and described with reference to embodiments thereof, it will be understood by those skilled in the art that various changes in form and details may be made without departing from the scope of the invention.

1. A driver monitoring system module comprising:
a housing;
a first circuit board; and
a second circuit board, wherein
(i) the first circuit board is mounted at a first location within the housing,
(ii) the second circuit board is mounted at a second location on an exterior surface of the housing,
(iii) the first circuit board and the second circuit board are partially overlapped in a first direction and separated by a predefined distance in a second direction, and
(iv) the exterior surface of the housing defines a passage between the first circuit board and the second circuit board that allows ambient air to pass between the first circuit board and the second circuit board to provide convective cooling.

2. The driver monitoring system module according to claim 1, wherein the first circuit board comprises a camera module and the second circuit board comprises an infra-red light emitting diode module.

3. The driver monitoring system module according to claim 2, wherein the camera module comprising an imaging sensor and a lens assembly.

4. The driver monitoring system module according to claim 3, wherein the lens assembly extends through the housing and the housing is configured to form an environmental seal with the lens assembly.

5. The driver monitoring system module according to claim 3, wherein the infra-red light emitting diode module is separated from an optical axis of the lens assembly to achieve a predetermined pupil illumination.

6. The driver monitoring system module according to claim 2, wherein the infra-red light emitting diode module comprises one or more infra-red light emitting diodes and driver circuitry.

7. The driver monitoring system module according to claim 1, wherein the housing comprises an upper housing and a lower housing, and the exterior surface of the upper housing defines the passage between the first circuit board and the second circuit board.

8. The driver monitoring system module according to claim 1, wherein the exterior surface of the upper housing further defines a finned structure.

9. The driver monitoring system module according to claim 1, further comprising a first connector configured to connect said first circuit board to an electronic bus of a vehicle.

10. The driver monitoring system module according to claim 9, further comprising a second connector configured to connect said second circuit board to an electronic bus of the vehicle.

11. A method of reducing heat transfer between an illuminator module and an imaging sensor chip of a driver monitoring system module comprising:
forming a housing comprising an exterior surface that defines a passage that allows ambient air to pass between a first mounting location and a second mounting location to provide convective cooling of said housing, wherein the first mounting location is within the housing and the second mounting location is on the exterior surface of the housing;
mounting a first circuit board comprising the imaging sensor chip and a lens assembly in the first mounting location; and
mounting a second circuit board comprising a plurality of infra-red light emitting diodes in the second mounting location, wherein portions of the first circuit board and the second circuit board are partially overlapped and the overlapped portions are separated by the passage defined by the exterior surface of the housing.

12. The method according to claim 11, wherein the housing comprises an upper housing and a lower housing, and the exterior surface of the upper housing defines the passage between the first circuit board and the second circuit board.

13. The method according to claim 11, further comprising forming the exterior surface of the housing to define a finned structure configured to provide additional convective cooling of the housing.

14. The method according to claim 11, wherein the first mounting location is configured to separate the plurality of infra-red light emitting diodes from an optical axis of the lens assembly by a distance configured to achieve a predetermined pupil illumination criteria.

15. The method according to claim 11, further comprising:
connecting the first circuit board to a first connector configured to connect the first circuit board to an electronic bus of a vehicle; and
connecting the second circuit board to a second connector configured to connect the second circuit board to the electronic bus of the vehicle.
